(19) United States
(12) Patent Application Publication
(10) Pub. No.: US 2024/0014072 A1
(43) Pub. Date: Jan. 11, 2024

(54) NITROGEN PLASMA TREATMENT FOR BOTTOM-UP GROWTH

(71) Applicant: Applied Materials, Inc., Santa Clara, CA (US)

(72) Inventors: Tsung-Han YANG, San Jose, CA (US); Zhimin QI, Santa Clara, CA (US); Yongqian GAO, Santa Clara, CA (US); Rongjun WANG, Dublin, CA (US); Yi XU, San Jose, CA (US); Yu LEI, Belmont, CA (US); Xingyao GAO, Santa Jose, CA (US); Chih-Hsun HSU, Santa Clara, CA (US); Xi CEN, San Jose, CA (US); Wei LEI, Santa Clara, CA (US); Shiyu YUE, Santa Clara, CA (US); Aixi ZHANG, Santa Clara, CA (US); Kai WU, Palo Alto, CA (US); Xianmin TANG, San Jose, CA (US)

(21) Appl. No.: 18/212,352

(22) Filed: Jun. 21, 2023

Related U.S. Application Data
(60) Provisional application No. 63/359,249, filed on Jul. 8, 2022.

(51) Int. Cl. H01L 21/768; H01J 37/32

(52) U.S. Cl. CPC H01L 21/76879; H01J 37/32449; H01J 37/32816; H01J 37/32422; H01J 2237/2001; H01J 37/321; H01J 2237/332

(57) ABSTRACT

A method of forming a semiconductor device structure includes forming a nucleation layer within at least one feature. The method includes exposing the nucleation layer to a nitrogen plasma treatment. The nitrogen plasma treatment preferentially treats the top field and sidewalls while leaving the bottom surface substantially untreated to encourage bottom up metal growth.

### CROSS-REFERENCE TO RELATED APPLICATIONS

This application claims the benefit of U.S. Provisional Patent Application Ser. No. 63/359,249, filed Jul. 8, 2022, which is incorporated by reference herein in its entirety.

### TECHNICAL FIELD

The present disclosure relates to a method and apparatus for forming thin-films. More particularly, the disclosure relates to a method and apparatus for metal gap-fill in semiconductor devices.

### BACKGROUND

The fabrication of microelectronic devices typically involves a complicated process sequence requiring hundreds of individual processes performed on semi-conductive, dielectric and conductive substrates. Examples of these processes include oxidation, diffusion, ion implantation, thin film deposition, cleaning, etching, lithography among other operations. Each operation is time consuming and expensive.

With ever-decreasing critical dimensions for microelectronic devices, the design and fabrication for these devices on substrates becomes increasingly complex. Control of the critical dimensions and process uniformity becomes increasingly more significant. Complex multilayer stacks involve precise process monitoring of the critical dimensions for the thickness, roughness, stress, density, and potential defects. Multiple incremental processes in the process recipes for forming the devices ensure critical dimensions are maintained. However, each recipe process may utilize one or more process chambers that adds additional time for forming the devices in the processing systems and also provides additional opportunities for forming defects. Thus, each process adds to the overall fabrication cost for the completed microelectronic devices.

Additionally, as critical dimensions on these devices shrink, past fabrication techniques encounter new hurdles. For example, as a liner and/or nucleation layer is prepared to grow a metal gap-fill, the liner and/or nucleation layer may be still be present on the sides of the gap causing the metal fill material to close off the gap prior to completely filling resulting in seams in the metal gap-fill material.

For at least the foregoing reasons, there is an ongoing need for improved fabrication methods to minimize cost while maintaining critical dimensions for microelectronic devices.

### SUMMARY

The present disclosure relates to a method and apparatus for forming thin-films. More particularly, the disclosure relates to a method and apparatus for tungsten gap-fill in semiconductor devices.

In one aspect, a method for processing a semiconductor device structure in a process chamber is provided. The method includes generating a plasma comprising nitrogen-containing radicals in a remote plasma source. The plasma is formed from a process gas comprising nitrogen and a noble gas. The method further includes flowing the plasma comprising the nitrogen-containing radicals into a processing region of the process chamber where the semiconductor device structure is disposed. The semiconductor device structure includes a feature formed thereon, the feature having sidewall surfaces and a bottom surface extending between the sidewall surfaces and a tungsten nucleation layer formed over the sidewall surfaces and the bottom surface. The method further includes exposing an exposed portion of the tungsten nucleation layer along the sidewall surfaces of the tungsten nucleation layer to the nitrogen-containing radicals to passivate the exposed portion of the tungsten nucleation layer while the tungsten nucleation layer formed along the bottom surface remains substantially un-passivated. The method further includes filling the feature with a tungsten layer, comprising preferentially growing the tungsten layer from the tungsten nucleation layer remaining on the bottom surface of the feature.

Embodiments may include one or more of the following. The method further includes maintaining a pressure within the processing region such that a nitrogen partial pressure in the processing region in a range from about 5 milliTorr to about 20 milliTorr. The pressure within the processing region is maintained in a range from about 1 Torr to about 10 Torr. Exposing the exposed portion of the tungsten nucleation layer along the sidewall surfaces of the tungsten nucleation layer to the nitrogen-containing radicals is performed for a time period in a range from about 5 seconds to about 40 seconds. The method further includes filtering out ions delivered from the remote plasma source to the processing region. The method further includes filtering ions from an output of the remote plasma source. Filling the feature with the tungsten layer is performed in the processing region. The process gas includes from about 5% to about 20% nitrogen and the remainder the noble gas, wherein the noble gas is argon.

In another aspect, a method for processing a semiconductor device structure in a process chamber is provided. The method includes generating a plasma comprising nitrogen-containing ions using an inductively coupled plasma (ICP) source. The plasma is formed from a process gas comprising nitrogen and a noble gas. The method further includes flowing the plasma comprising the nitrogen-containing ions into a processing region of the process chamber where the semiconductor device structure is disposed. The semiconductor device structure has a feature formed thereon, the feature having sidewall surfaces and a bottom surface extending between the sidewall surfaces and a tungsten nucleation layer formed over the sidewall surfaces and the bottom surface. The method further includes exposing an exposed portion of the tungsten nucleation layer along the sidewall surfaces of the tungsten nucleation layer to the nitrogen-containing ions to passivate the exposed portion of the tungsten nucleation layer. The tungsten nucleation layer formed along the bottom surface remains substantially un-passivated. The method further includes filling the feature with a tungsten layer, including preferentially growing the tungsten layer from the tungsten nucleation layer remaining on the bottom surface of the feature.

Embodiments may include one or more of the following. The method further includes maintaining a pressure within the processing region such that a nitrogen partial pressure in the processing region is in a range from about 0.01 milliTorr to about 0.05 milliTorr. The pressure within the processing region is maintained in a range from about mTorr to about 20 mTorr. Exposing the exposed portion of the tungsten nucleation layer along the sidewall surfaces of the tungsten nucleation layer to the nitrogen-containing ions is performed for a time period in a range from about 3 seconds to about seconds. The method further includes filtering out radicals delivered from the ICP source to the processing region. The method further includes filtering radicals from an output of the ICP source. Filling the feature with the tungsten layer is performed in the processing region. The process gas comprises from about 1% to about 10% nitrogen and the remainder the noble gas, wherein the noble gas is argon.

In yet another aspect, a method for processing a semiconductor device structure in a process chamber is provided. The method includes exposing a semiconductor device structure to nitrogen-containing ions in a processing region of the process chamber. The semiconductor device structure has a feature formed thereon, the feature having sidewall surfaces and a bottom surface extending between the sidewall surfaces, one or more conformal/nonconformal layers formed over the sidewall surfaces and the bottom surface, and a boron-tungsten nucleation layer formed over the one or more conformal/nonconformal layers, wherein an exposed portion of the tungsten nucleation layer along the sidewall surfaces of the tungsten nucleation layer is passivated by the nitrogen-containing ions to suppress subsequent tungsten growth, and the boron-tungsten nucleation layer formed along the bottom surface remains substantially un-passivated. The method further includes partially filling the feature with a tungsten layer, including preferentially growing the tungsten layer from the tungsten nucleation layer remaining on the bottom surface of the feature. The method further includes repeating the exposing the semiconductor device structure to the nitrogen-containing ions in the processing region and partially filing the feature with the tungsten layer until the tungsten layer achieves a targeted thickness.

Embodiments may include one or more of the following. The method further includes maintaining a pressure within the processing region such that a nitrogen partial pressure in the processing region is in a range from about 0.01 milliTorr to about 0.05 milliTorr. The pressure within the processing region is maintained in a range from about 5 mTorr to about 20 mTorr. Exposing the exposed portion of the boron-tungsten nucleation layer along the sidewall surfaces to the nitrogen-containing ions is performed for a time period in a range from about 3 seconds to about 20 seconds.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the aspects, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a flow chart of a method for manufacturing a semiconductor device in accordance with one or more embodiments of the present disclosure.

FIGS. 2A-2H illustrate views of various stages of manufacturing a semiconductor device in accordance with one or more embodiments of the present disclosure.

FIG. 3 illustrates a schematic top view of one example of a multi-chamber processing tool in accordance with one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the Summary above and in the Detailed Description, and the claims below, and in the accompanying drawings, reference is made to particular features (including method operations) of the present disclosure. It is to be understood that the disclosure in this specification includes all possible combinations of such particular features. For example, where a particular feature is disclosed in the context of a particular aspect or embodiment of the present disclosure, or a particular claim, that feature can also be used, to the extent possible in combination with and/or in the context of other particular aspects and embodiments of the present disclosure, and in the present disclosure generally.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components.

Where reference is made herein to a method comprising two or more defined operations, for example, processes, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

The deposition of gap-fill metal thin films, for example, tungsten, copper, cobalt, ruthenium, or molybdenum-containing thin films, in features with ultra-high aspect ratios is challenging. At earlier nodes, larger dimensions made metal gap-fill possible using nucleation followed by conformal chemical vapor deposition (CVD). However, as the critical dimensions of features continue to shrink, the tops of the ultra-small features are prone to overhang so the conformal process in which the film grows equally on the field region or surface closes or pinches off the opening before filling is complete, leaving voids in the metal gap-fill. Even in the absence of voids, center seams are a typical result of conformal deposition as the metal gap-fill grows from the sidewall. This incomplete fill may lead to high resistance. Metal gap-fill may also be adversely affected by the presence of impurities. The presence of fluorine-terminated (F-terminated) impurities on the surface of underlying layers, for example, liners, barriers, and/or nucleation layers, present in the feature. Other impurities such as boron, nitrogen, and oxides may also adversely affect metal gap-fill. For example, in some conventional bottom-up metal fill processes incorporating nucleation layers having contaminants, it is not uncommon to have a 15-20% resistance penalty when compared to metal gap-fill without nucleation layers.

Various embodiments provide improved metal gap-fill in features having reduced critical dimensions. Various embodiments utilize a nitrogen (e.g., N2, NO, NO2, and N2H4) plasma including nitrogen-containing ions or nitrogen-containing radicals with the proper process conditions to achieve nearly conformal treatment inside the feature. This conformal treatment inside the feature enables bottom-up growth before losing the incubation delay at the top-field and sidewall. It has been found by the inventors that treating underlying films deposited along the top field and sidewalls with the nitrogen plasma treatment described herein provides conformal treatment of top field and sidewall. This conformal treatment delays incubation/growth of the metal-fill along the top field and sidewalls, which enables bottom-up growth of the metal-fill. The bottom-up growth provides for the growth of big grains within the feature instead of smaller grains, which are typically formed using conventional bottom-up growth approaches. The improved conformal treatment described herein provides for large grain growth, resulting in no resistance, a reduced resistance penalty, or in some cases a resistance benefit. Some embodiments may provide improved Rs/Rc performance relative to conventional deposition only and overcome the Rs penalty, which is normally observed in conventional metal gap-fill.

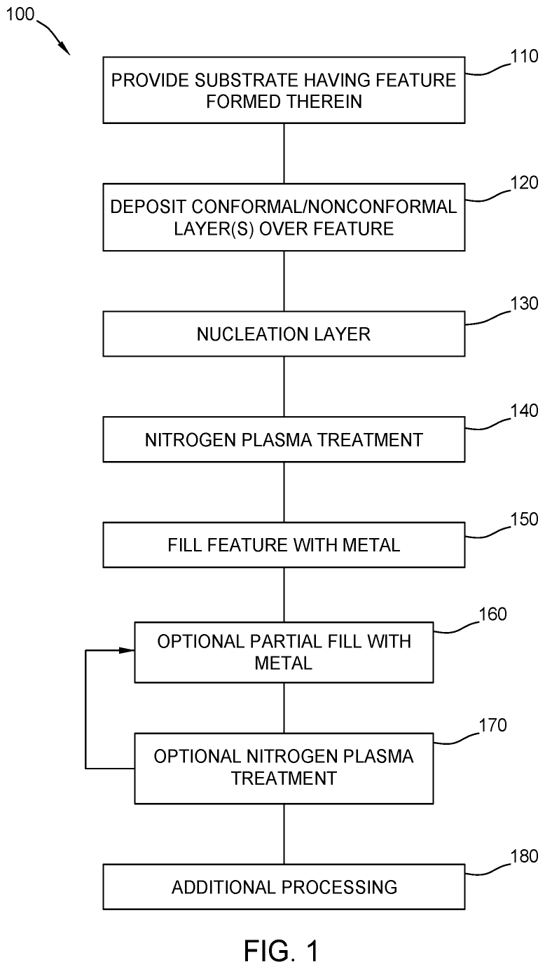

FIG. 1 illustrates a flow chart of a method 100 for manufacturing a semiconductor device in accordance with one or more embodiments of the present disclosure. At operation 110, a substrate is provided. The substrate may be a device substrate or a semiconductor substrate as described herein. The substrate may include multiple layers. The substrate has one or more features formed therein. The one or more features may include a sidewall surface and a bottom surface. The sidewall surface may be defined by a dielectric material and the bottom surface may be defined by a dielectric material or other materials, for example, a silicide layer, a metal silicide layer, a semiconductor layer, an etch stop layer (ESL), or a metal layer.

At operation 120, one or more conformal/nonconformal layers may be formed over the surfaces of the one or more features. The one or more conformal/nonconformal layers can include one or more of barrier, adhesion, and/or liner layers. The one or more conformal/nonconformal layers can include or be a nitride, for example, silicon nitride, carbon nitride, aluminum nitride, tantalum nitride, titanium nitride, tungsten nitride, the like, or a combination thereof, or a metal, for example, tantalum, cobalt, titanium, tungsten, copper, ruthenium, the like, or a combination thereof, or a carbide, for example, tungsten carbide, aluminum carbide, the like, or a combination thereof. The one or more conformal/nonconformal layers may be formed by any suitable deposition process such as ALD, CVD, PVD, or a hybrid ALD/CVD process. The one or more conformal/nonconformal layers may create an overhang portion in the field region, which obstructs or blocks top openings of the one or more features leading to the formation of seams in the metal gap-fill.

At operation 130, a nucleation layer may be formed over the feature or the one or more conformal/nonconformal layers (if present). The nucleation layer may be used to repair any damage or discontinuities in the one or more conformal/nonconformal layers. The nucleation layer may be a tungsten-containing nucleation layer such as a boron-tungsten (BW) nucleation layer, a boron-silicon-tungsten (BSW) nucleation layer, or a silicon-tungsten (SW) nucleation layer. Any suitable deposition process may be used to deposit the nucleation layer. The deposition process may be an atomic layer deposition (ALD) process, a cyclic chemical vapor deposition (CCVD) process, or a combination thereof (e.g., a hybrid ALD/CVD process). In one example, one cycle of the ALD process includes a boron pulse/a boron purge/a tungsten pulse/a tungsten purge. The ALD process may be repeated for any number of cycles sufficient to deposit a nucleation layer of targeted thickness. In one example, the ALD cycle is repeated for 3 to 5 cycles. The nucleation layer may also contribute to the thickness of the overhang portion (if present) formed by the one or more conformal/nonconformal layers during operation 120.

At operation 140, the substrate is exposed to a nitrogen plasma treatment. In some embodiments, the nitrogen plasma treatment process of operation 140 may include exposing a portion of the underlying layers (e.g., the one or more conformal/nonconformal layer and/or nucleation layer) to a nitrogen plasma treatment process. In some embodiments the nitrogen plasma treatment process is an inductively coupled plasma process. In some embodiments, the nitrogen plasma treatment process is a capacitively coupled plasma process. In some embodiments, the nitrogen plasma is formed in a remote plasma source (RPS). In some embodiments, the nitrogen plasma is generated within the processing region (e.g., a direct plasma). In some embodiments, the nitrogen plasma treatment process includes exposing the nucleation layer to a plasma formed from a process gas including a nitrogen-containing gas. The nitrogen-containing gas may be selected from N2, NO, NO2, N2H4, or a combination thereof. The process gas may further include an inert gas, for example, argon (Ar), helium (He), krypton (Kr), or a combination thereof. The process gas may include argon (Ar), helium (He) hydrogen (H2), nitrogen (N2), or a H2/N2 mixture. In some embodiments, the plasma treatment process includes exposing the nucleation layer to an ICP formed from a process gas including a nitrogen-containing gas (e.g., N2) and an inert gas (e.g., Ar). In some embodiments, the plasma treatment process can include exposing the underlying layers to a plasma formed in an RPS form a process gas including one or more of N2 and Ar. In some embodiments, the nitrogen plasma treatment process can include exposing the nucleation layer to a plasma including either substantially radicals (nitrogen radicals) or substantially ions (nitrogen ions).

At operation 150, the one or more features may be filled with a metal-fill material, for example, tungsten, copper, cobalt, ruthenium, or molybdenum metal-fill. In one example, where the metal-fill is tungsten, the tungsten layer may be a tungsten gap-fill layer. Any suitable metal-fill deposition process may be used to deposit the metal gap-fill layer. The metal gap-fill layer may be deposited via a CVD gap-fill process, an ALD gap-fill process, or a hybrid ALD/CVD process. The metal gap-fill layer may partially or completely fill the one or more features. Due to the nitrogen plasma treatment of operation 140, the clean surfaces of the underlying metal-containing layers (e.g., conformal layers and/or nucleation layer) provide for good gap-fill by the metal gap-fill layer with reduced Rs in the final device. In some embodiments, the feature may be partially filled with metal-fill at operation 160 followed by additional nitrogen plasma treatment of the partial metal-fill at operation 170. The nitrogen plasma treatment of operation 170 may be performed similarly to the nitrogen plasma treatment of operation 140. Operation 160 and operation 170 may be repeated until the metal-fill material reaches a targeted thickness within the feature.

At operation 180, additional processing may be performed. In some embodiments, a planarization process, for example a CMP process or an etchback process may be performed to remove excess portions or overburden of the metal-fill material (if present). In some embodiments, an annealing process may be performed during operation 180.

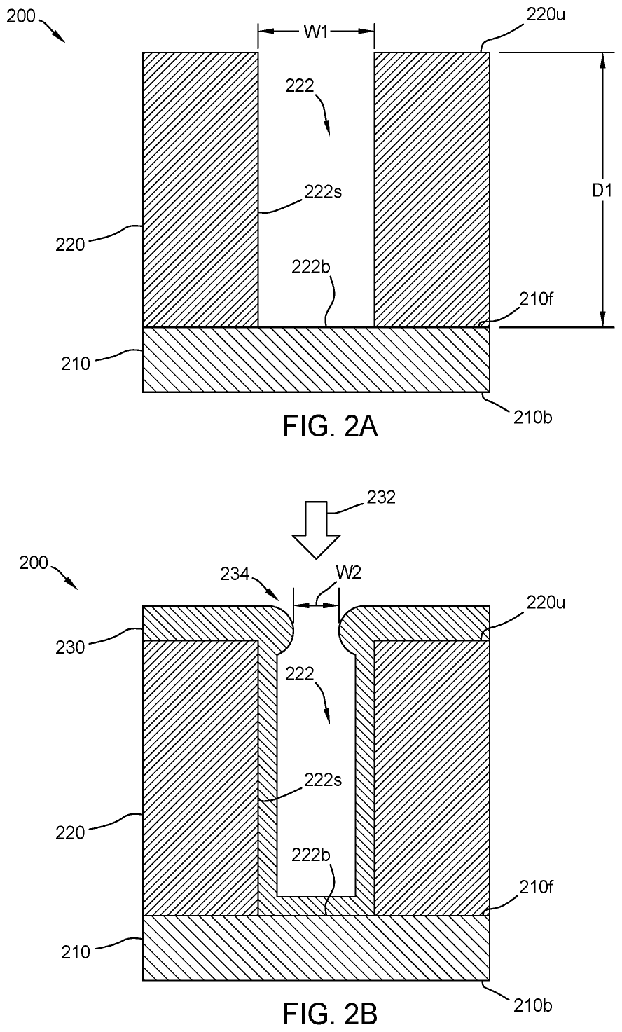

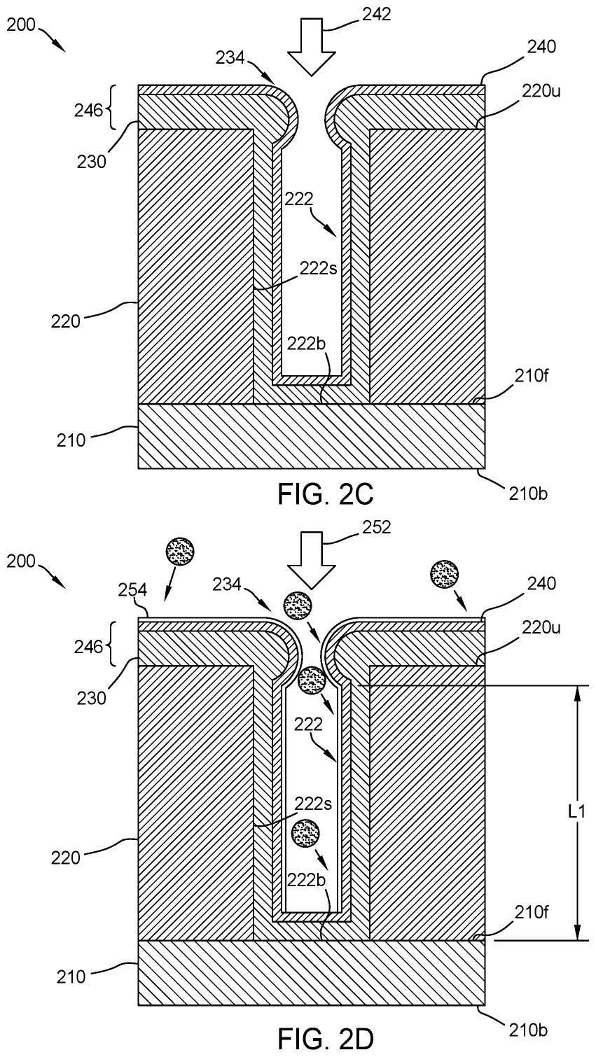

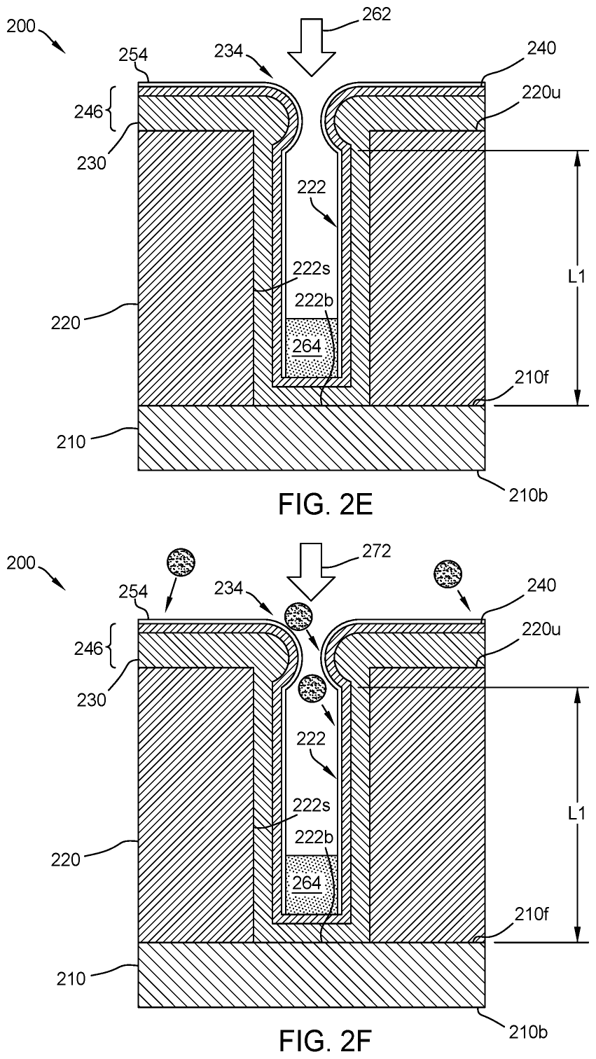

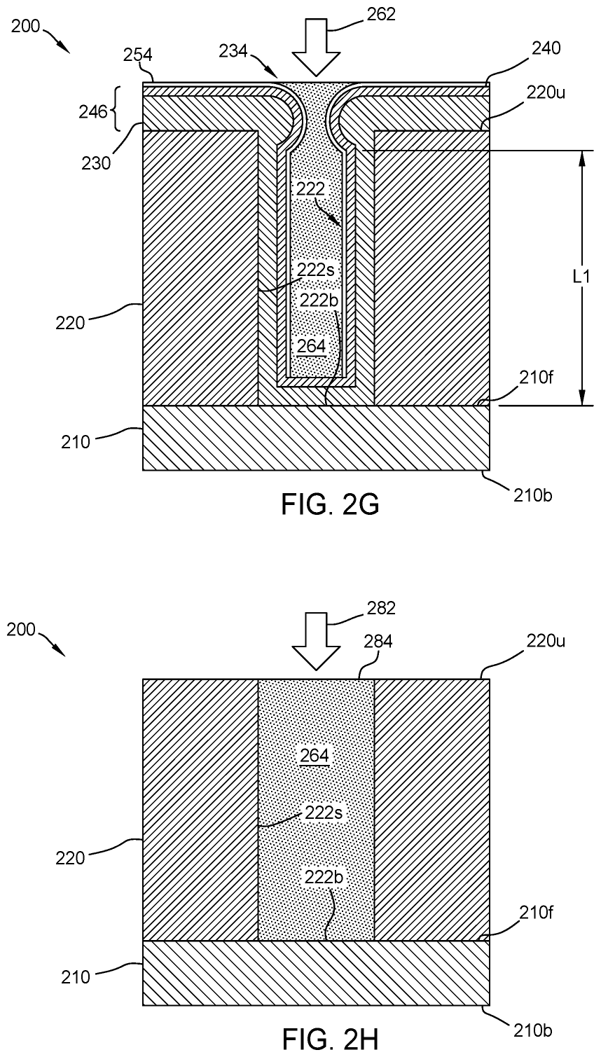

With reference to FIGS. 2A-2H, cross-sectional views of some embodiments of a device structure for semiconductor devices at various stages of manufacture are provided to illustrate the method of FIG. 1. Although FIGS. 2A-2H are described in relation to the method 100, it will be appreciated that the structure disclosed in FIGS. 2A-2H are not limited to the method 100, but instead may stand alone as structures independent of method 100. Similarly, although the method 100 is described in relation to FIGS. 2A-2H, it will be appreciated that the method 100 is not limited to the structures disclosed in FIGS. 2A-2H, but instead may stand alone independent of the structures disclosed in FIGS. 2A-2H.

FIGS. 2A-2H illustrate views of various stages of manufacturing a semiconductor device in accordance with one or more embodiments of the present disclosure.

FIG. 2A illustrates a cross-sectional view of a semiconductor device structure 200 during intermediate stages of manufacturing corresponding to operation 110, in accordance with some embodiments. The semiconductor device structure 200 includes a device substrate 210 having one or more layers formed thereon, for example, a dielectric layer 220 as is shown in FIG. 2A. The device substrate 210 may be or include a bulk semiconductor substrate, a semiconductor-on-insulator (SOI) substrate, or the like, which may be doped (e.g., with a p-type dopant or an n-type dopant) or undoped. In some embodiments, the semiconductor material of the device substrate 210 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 210 may include additional materials, for example, silicide layers, metal silicide layers, metal layers, dielectric layers, etch stop layers, interlayer dielectrics, or a combination thereof.

The device substrate 210 may further include integrated circuit devices (not shown). As one of ordinary skill in the art will recognize, a wide variety of integrated circuit devices such as transistors, diodes, capacitors, resistors, the like, or combinations thereof may be formed in and/or on the device substrate 210 to generate the structural and functional requirements of the design for the resulting semiconductor device structure 200.

The device substrate 210 has a frontside 210f (also referred to as a front surface) and a backside 210b (also referred to as a back surface) opposite the frontside 210f. The dielectric layer 220 is formed over the frontside 210f of the device substrate 210. The dielectric layer 220 may include multiple layers. The dielectric layer 220 includes an upper surface 220u or field region. In some embodiments, the dielectric layer 220 includes silicon oxide, silicon oxynitride, silicon nitride, a combination thereof, or multi-layers thereof. In some embodiments, the dielectric layer 220 consists essentially of silicon oxide. It is noted that the foregoing descriptors (e.g., silicon oxide) should not be interpreted to disclose any particular stoichiometric ratio. Accordingly, “silicon oxide” and the like will be understood by one skilled in the art as a material consisting essentially of silicon and oxygen without disclosing any specific stoichiometric ratio.

The dielectric layer 220 is patterned to form one or more feature(s) 222. In some embodiments, the feature 222 can be selected from a trench, a via, a hole, or combinations thereof. In particular embodiments the feature 222 is a via. In some embodiments, the feature 222 extends from the upper surface 220u of the dielectric layer 220 to the frontside 210f of the device substrate 210. The feature 222 includes sidewall surface 222s and a bottom surface 222b extending between the sidewall surface 222s. In some embodiments, the sidewall surface 222s is tapered. The sidewall surface 222s may be defined by the dielectric layer 220 and the bottom surface may be defined by the device substrate 210. In some embodiments, the sidewall surface 222s may be defined by the dielectric layer 220 and the bottom surface may also be defined by the dielectric layer 220. The feature 222 has a first depth “D1” from the upper surface 220u to the bottom surface 222b and a width “W1” between the two sidewall surface 222s. In some embodiments, the depth D1 is in a range of 2 nm to 200 nm, 3 nm to 200 nm, 5 nm to 100 nm, 2 nm to 100 nm, or 50 nm to 100 nm. In some embodiments, the width W1 is in a range of 10 nm to 100 nm, 10 nm to 20 nm, 10 nm to 50 nm, or 50 nm to 100 nm. In some embodiments, the feature 222 has an aspect ratio (D/W) in a range of 1 to 20, 5 to 10 to 20, or 15 to 20.

FIG. 2B illustrates a cross-sectional view of the semiconductor device structure 200 during intermediate stages of manufacturing corresponding to operation 120, in accordance with some embodiments. At operation 120, one or more conformal/nonconformal layers 230 may be formed over the surfaces of the feature 222. The one or more conformal/nonconformal layers 230 can include one or more barrier, adhesion, and/or liner layers. The one or more conformal/nonconformal layers 230 can include or be a nitride, for example, silicon nitride, carbon nitride, aluminum nitride, tantalum nitride, titanium nitride, tungsten nitride, the like, or a combination thereof, or a metal, for example, tantalum, cobalt, titanium, tungsten, the like, or a combination thereof, or a carbide, for example, tungsten carbide, aluminum carbide, the like, or a combination thereof. The one or more conformal/nonconformal layers 230 may be formed by a conformal/nonconformal layer deposition process 232. The one or more conformal/nonconformal layers 230 may be formed by any suitable conformal/nonconformal layer deposition process such as ALD, CVD, PVD, or a hybrid ALD/CVD process.

The one or more conformal/nonconformal layers 230 may be formed over the sidewall surface 222s and the bottom surface 222b of the feature 222 and on the upper surface 220u or field region of the dielectric layer 220. In some embodiments, the one or more conformal/nonconformal layers 230 include a barrier layer having a liner layer formed thereon, for example, a titanium nitride barrier layer having a tungsten liner formed thereon. In some embodiments, the one or more conformal/nonconformal layers 230 include a liner layer formed over the surfaces of the feature 222. The one or more conformal/nonconformal layers 230 may include or be a liner layer. The liner layer may be a tungsten liner layer. The liner layer may have an initial thickness in a range from about 1 Å to about 100 Å, or in a range from about 20 Å to about 50 Å. In some embodiments, the one or more conformal/nonconformal layers 230 may be discontinuous along for example, the sidewall surface 222s and/or the bottom surface 222b. In particular embodiments, the one or more conformal/nonconformal layers 230 include a tungsten-liner layer, which is formed via a PVD process. As depicted in FIG. 2B, the liner layer may create an overhang portion 234 along the upper surface 220u or the field region of the dielectric layer 220. The overhang portion 234 may partially obstruct or block the top opening of the feature 222. The overhang portion 234 may reduce the width of the top opening from W1 as shown in FIG. 2A to W2 as shown in FIG. 2B.

FIG. 2C illustrates a cross-sectional view of the semiconductor device structure 200 during intermediate stages of manufacturing corresponding to operation 130, in accordance with some embodiments. At operation 130, a nucleation layer, for example, a nucleation layer 240 is formed over the surfaces of the feature 222, for example, over the surface of the one or more conformal/nonconformal layers 230. The nucleation layer 240 may function as a seed layer for subsequent deposition of the metal-fill material. In addition, in some embodiments where the previously deposited one or more conformal/nonconformal layers 230 are discontinuous, for example, along the sidewall surface 222s, the nucleation layer 240 may repair discontinuous portions of the one or more conformal/nonconformal layers 230. The nucleation layer 240 may include or be any suitable material for facilitating the growth of the subsequently deposited metal-fill material. The nucleation layer 240 can include or be a metal, for example, tantalum, cobalt, titanium, tungsten, ruthenium, the like, or a combination thereof, or a metal-boride, for example, tungsten-boride, or the like. The nucleation layer 240 may be formed by a nucleation layer deposition process 242. Any suitable nucleation layer deposition process such as ALD, CVD, PVD, or a hybrid ALD/CVD process may be used.

In some embodiments, the nucleation layer 240 may include or be a tungsten-containing nucleation layer, for example, a boron-tungsten (BW) nucleation layer, a boron-silicon-tungsten (BSW) nucleation layer, or a silicon-tungsten (SW) nucleation layer. The nucleation layer 240 may be a conformal layer. In some embodiments, the one or more conformal/nonconformal layers 230 include a barrier and/or liner layer having the nucleation layer 240 formed thereon, for example, a tungsten liner layer having a boron-tungsten nucleation layer formed thereon. In some embodiments, the one or more conformal/nonconformal layers 230 and the nucleation layer 240 may be referred to individually or together as tungsten-containing layers or the underlying layers 246 as depicted in FIG. 2C.

In some embodiments where the nucleation layer 240 is a tungsten-containing nucleation layer, forming the nucleation layer 240 at operation 130 includes exposing the semiconductor device structure 200 to a tungsten-containing precursor gas at a first precursor gas flow rate followed by exposing the semiconductor device structure 200 to a reducing agent. The reducing agent may include boron and is introduced to the processing region at a reducing agent flow rate. The tungsten-containing precursor gas and the reducing agent may be alternated cyclically to form the nucleation layer 240 over the semiconductor device structure 200 within the feature 222 at the reducing agent flow rate. The reducing agent and the tungsten-containing precursor gas may be cyclically alternated, beginning with either the reducing agent or the tungsten-containing precursor gas, and ending with the same beginning gas or ending with a gas different from the beginning gas. In some embodiments, the reducing agent or the tungsten-containing precursor gas are cyclically alternated beginning with the tungsten-containing precursor gas and ending in the reducing agent.

In some embodiments, the nucleation layer 240 is deposited using the ALD process. The ALD process includes repeating cycles of alternately exposing the feature 222 to a tungsten-containing precursor and exposing the feature 222 to a reducing agent. In some embodiments, the processing region is purged between the alternating exposures. In some embodiments, the processing region is continuously purged. Examples of suitable tungsten-containing precursors include tungsten halides, such as tungsten hexafluoride (WF₆), tungsten hexachloride (WCl₆), or a combination thereof. In some embodiments, the tungsten-containing precursor includes WF₆, and the reducing agent includes a boron-containing agent, such as B₂H₆. In some embodiments, the tungsten-containing precursor includes an organometallic precursor and/or a fluorine-free precursor, for example, MDNOW (methylcyclopentadienyl-dicarbonylnitrosyl-tungsten), EDNOW (ethylcyclopentadienyl-dicarbonylnitrosyl-tungsten), tungsten hexacarbonyl (W(CO)₆), or a combination thereof.

In some embodiments, during the nucleation layer deposition process 242, the processing region is maintained at a pressure of less than about 120 Torr, such as in a range from about 900 mTorr to about 120 Torr, in a range from about 1 Torr to about 100 Torr, or for example, in a range from about 1 Torr to about 50 Torr. Exposing the semiconductor device structure 200 to the tungsten-containing precursor includes flowing the tungsten-containing precursor into the processing region at a flow rate of about 100 sccm or less, such as in a range from about 10 sccm to about 60 sccm, or in a range from about 20 sccm to about 80 sccm. Exposing the semiconductor device structure 200 to the reducing agent includes flowing the reducing agent into the processing region at a flow rate in a range from about 200 sccm to about 1000 sccm, such as in a range from about 300 sccm to about 750 sccm. It should be noted that the flow rates for the various deposition and treatment processes described herein are for a processing system configured to process a 300 mm diameter substrate. Appropriate scaling may be used for processing systems configured to process different-sized substrates.

In some embodiments, the tungsten-containing precursor and the reducing agent are each flowed into the processing region for a duration in a range from about 0.1 seconds to about 10 seconds, such as in a range from about 0.5 seconds to about 5 seconds. The processing region may be purged between the alternating exposures by flowing a purge gas, such as argon (Ar) or hydrogen gas, into the processing region for a duration in a range from about 0.1 seconds to about 10 seconds, such as in a range from about 0.5 seconds to about 5 seconds. Typically, the repeating cycles of the nucleation process continue until the nucleation layer 240 has a thickness in a range from about 10 Å to about 200 Å, such as in a range from about 10 Å to about 150 Å, or in a range from about 20 Å to about 150 Å. In one example, the ALD cycle is repeated for 3 to 5 cycles. The nucleation layer 240 is disposed along sidewall surface 222s and or the bottom surfaces 222b of the feature 222, such as over the one or more conformal/nonconformal layers 230. The nucleation layer 240 may also contribute to the thickness of the overhang portion 234 formed by the liner layer during operation 120.

FIG. 2D illustrates a cross-sectional view of the semiconductor device structure 200 during intermediate stages of manufacturing corresponding to operation 140, in accordance with some embodiments. At operation 140, the semiconductor device structure 200 is exposed to a nitrogen plasma treatment process 252. The nitrogen plasma treatment process 252 utilizes ion and/or radical based nitrogen plasma to achieve conformal treatment by forming a nitrogen passivation layer 254 along the upper surface 220u or field region, the overhang portion 234, and inside the feature 222 along the sidewall surface 222s while leaving the bottom surface 222b substantially uncoated. In some embodiments, as shown in FIG. 2D, the nitrogen passivation layer 254 coats the nucleation layer 240. The nitrogen passivation layer 254 suppresses growth of the subsequently deposited metal-fill material along the passivated regions (e.g., the upper surface 220u, the overhang portion 234, and/or the sidewall surface 222s while enabling bottom-up growth from the nucleation layer 240 formed over the bottom surface 222b. The nitrogen passivation layer 254 may be partially formed along the length “L1” of the sidewall surface 222s. For example, referring to FIG. 2D, the nitrogen passivation layer 254 may be formed along greater than or equal to 50% of “L1,” or greater than or equal to 60% of “L1,” or greater than or equal to 70% of “L1,” or greater than or equal to 80% of “L1,” or greater than or equal to 90% of “L1,” or equal to 100% of “L1.”

In some embodiments, the nitrogen plasma treatment process 252 includes a plasma formed from an inductively coupled plasma source. In some embodiments, the nitrogen plasma treatment process 252 includes a plasma formed from a capacitively coupled plasma source. In some embodiments, the nitrogen plasma treatment process 252 includes a plasma formed in a remote plasma source (RPS). In some embodiments, the plasma of the nitrogen plasma treatment process 252 treatment process includes a plasma generated within the processing region (e.g., a direct plasma). In some embodiments, the nitrogen plasma treatment process can include exposing the semiconductor device structure 200 or underlying layers 246 to a plasma formed from a process gas including a nitrogen-containing gas and optionally an inert or noble gas. The nitrogen-containing gas can be or include N₂, NO, N₂O, NO₂, N₂H₄, or a combination thereof. The noble gas can be or include Ar, He, or Kr. In particular embodiments, the nitrogen-containing gas can include or be N₂ and the noble gas can include or be Ar. In some embodiments, the nitrogen plasma treatment process 252 can include exposing the underlying layers 246 to an ICP formed from a process gas including nitrogen and optionally a noble gas. In some embodiments, the nitrogen plasma treatment process 252 can include exposing the underlying layers 246 to a plasma formed from N2 and one or more of Ar, He, or a combination thereof.

In some embodiments, the nitrogen plasma treatment process 252 can include exposing the semiconductor device structure 200 or underlying layers 246 to a plasma including either substantially radicals (nitrogen-containing radicals) or substantially ions (nitrogen-containing ions). The nitrogen-containing radicals may be or include N radicals, NO radicals, NH radicals, or NH2 radicals. In some embodiments, the plasma including substantially radicals further includes radicals from the noble gas.

In some embodiments, the semiconductor device structure 200 may be heated prior to or during the nitrogen plasma treatment process 252. For example, heating the semiconductor device structure 200 at a temperature of at least about 250 degrees Celsius, or at least about 350 degrees Celsius may facilitate the efficacy of the nitrogen plasma treatment process 252 of the underlying layers 246. In some embodiments, the substrate may be heated at a temperature from about 250 to about 550 degrees Celsius, or in some embodiments, from about 350 to about 450 degrees Celsius. The actual maximum substrate temperature may vary based upon hardware limitations and/or the thermal budget of the substrate being processed.

In some embodiments, during the nitrogen plasma treatment process 252 the processing region is maintained at a pressure of less than or equal to about 20 Torr, or of less than or equal to about 10 Torr, or less than or equal to about 5 Torr, or less than or equal to about 1 Torr, or less than or equal to about 20 mTorr, or less than or equal to about 10 mTorr, such as in a range from about 1 mTorr to about 20 mTorr, or in a range from about 5 mTorr to about 20 Torr, or in a range from about 1 mTorr to about 10 mTorr, or in a range from about 5 mTorr to about 10 mTorr, or in a range from about 1 Torr to about 20 Torr; or in a range from about 1 Torr to about 10 Torr, or in a range from about 1 Torr to about 5 Torr.

In some embodiments, the nitrogen plasma treatment process 252 can include exposing the underlying layers 246 to a radio frequency (RF) plasma, for example, ICP, CCP, or RPS, formed from a process gas including nitrogen and optionally a noble gas. The process gas may include 1 to 20% of N2, or 1 to 10% of N2, or 5 to 20%, with the balance being a noble gas. In some embodiments, the process gas may be N2 or a mixture of N2 and a noble gas. The noble gas may be, for example, argon (Ar), helium (He), krypton (Kr), or the like. In some embodiments, the process gas includes nitrogen (N2) and argon (Ar). In some embodiments, the process gas consists only of nitrogen (N2) and the noble gas. In some embodiments, the process gas may be predominantly comprised of or may consist essentially of nitrogen (N2) and the noble gas.

In some embodiments, the process gas may be supplied at a total gas flow in a range from about 100 to about 1000 sccm, or at about 400 sccm (although other flow rates may be used depending upon the application and configuration of the process chamber). In some embodiments, the process gas may include about 10-100 percent N2 (e.g., an N2 flow in a range from about 100 to about 1000 sccm). In some embodiments, the process gas may include about 0.5-99 percent N2 (e.g., an N2 flow in a range from about 5 to about 990 sccm) with the balance being essentially a noble gas, for example, argon (Ar) (e.g., a noble gas percentage in a range from about 1 to about 99.5 percent). In some embodiments, the process gas may be about 0.5-15 percent N2 (e.g., an N2 flow of between about 5-150 sccm) with the balance being essentially a noble gas, such as argon (e.g., a noble gas percentage of about 85 to about 99.5 percent). In some embodiments, the process gas may be about 0.5-10 percent N2 (e.g., an N2 flow of between about 5-100 sccm) with the balance being essentially a noble gas, such as argon (e.g., a noble gas percentage of about 90 to about 99.5 percent). In some embodiments, the process gas may be about 1-5 percent N2 (e.g., an N2 flow of between about 10-50 sccm) with the balance being essentially a noble gas, such as argon (e.g., a noble gas percentage of about 95 to about 99 percent). In some embodiments, the process gas may be about 2.5 percent of N2 (e.g., an N2 flow of about 25 sccm when 1000 sccm total gas flow is provided) with the balance being essentially a noble gas, for example, argon (e.g., a noble gas percentage of about 97.5 percent).

The process gas may be introduced into an RPS or a processing region of a process chamber, for example, a plasma reactor, and used to form a plasma. The plasma may be formed by using an RF source power. In some embodiments, the RF source power is up to about 5000 Watts, for example, in a range from about 10 Watts to about 500 Watts. The RF source power may be provided at any suitable RF frequency. For example, in some embodiments, the RF source power may be provided at a frequency about 2 to about 60 MHz, for example, about 13.56 MHz.

The plasma may be pulsed or continuously applied at up to about 5000 Watts. For example, the plasma may applied continuously at up to about 5000 Watts for a duration in a range from about 1 second to about 240 seconds, or in a range from about 3 seconds to about 20 seconds, or in a range from about 5 seconds to about 40 seconds. The duration may be adjusted (e.g., shortened) to limit damage to the semiconductor device structure 200. Alternatively, the plasma may be pulsed at a pulse frequency of about 4 kHz to about 15 kHz. The pulsed plasma may have a duty cycle of about 2% to about 70%, at up to 2000 watts peak power, where the duty cycle and/or RF source power may be adjusted to limit damage to the semiconductor device structure 200. In some embodiments, the pulsed plasma may have a duty cycle of about 30% to about 70%, at up to 4000 Watts peak power, where the duty cycle and/or RF source power may be adjusted to limit damage to the semiconductor device structure 200.

In some embodiments, it is preferred that the plasma substantially contain nitrogen radicals. Nitrogen radicals may be preferred in some embodiments because ions have high chemical activity compared to radicals, so ions do not achieve the selectivity of radicals. High radical density versus ion density may be achieved by a high pressure plasma process using, for example, a pressure in a range from about 1 Torr to about 20 Torr, for example, about 5 Torr or less. The high pressure encourages ions to recombine with electrons quickly, leaving neutral radical species and inactive species. In some embodiments, a radical gas is formed. In some embodiments, a remote plasma may be used to selectively generate radical species by various methods. In some embodiments, ions delivered from the remote plasma source to the processing region are filtered out of the plasma before reaching the processing region. In some embodiments, ions are filtered from the plasma at an output of the remote plasma source. The remote plasma generator, for example a microwave, RF, or thermal chamber, may be connected to a process chamber through a delivery pipe. The delivery pipe, may be a relatively long pathway positioned at an angle relative to the process chamber to encourage recombination of ionic species along the pathway before reaching the processing region. The radicals flowing through the delivery pipe may flow into the chamber through a showerhead or radical distributor, or through a portal entry in a sidewall of the chamber at a flow rate between about 1 slm and about 20 slm, such as between about 5 slm and about 20 slm, for example about 10 slm. Higher pressures and lower flows are believed to promote collisions. Nitrogen radicals may be formed in one embodiment by exposing the nitrogen-containing gas, such as nitrogen, optionally with a carrier gas such as argon, to microwave power between about 1-3 kW at a pressure of about 5 Torr or less.

In an embodiment where the plasma includes substantially nitrogen radicals, the semiconductor device structure 200 is exposed to a plasma formed from a process gas including 5 to 20% nitrogen (N2) and the remainder argon, at a partial pressure of nitrogen in a range from about 5 mTorr to about 20 mTorr, for example, 10 mTorr, for a time period in a range from about 5 to about 40 seconds. Not to be bound by theory but it is believe that performing the nitrogen plasma treatment process 252 at a nitrogen partial pressure less than 5 mTorr does not provide enough nitrogen radicals to ensure sufficient sidewall passivation by the nitrogen radicals and performing the nitrogen plasma treatment process 252 at a nitrogen partial pressure greater than 20 mTorr provides too many nitrogen radicals, which may passivate the bottom surface of the feature preventing bottom-up growth.

In an embodiment where the plasma includes substantially nitrogen ions, the semiconductor device structure 200 is exposed to a plasma formed from a process gas including 1 to 10% nitrogen (N2) and the remainder argon, at a partial pressure of nitrogen in a range from about 0.01 mTorr to about 0.05 mTorr, for example, 0.025 mTorr, for a time period in a range from about 3 to about 20 seconds.

FIG. 2E illustrates a cross-sectional view of the semiconductor device structure 200 during intermediate stages of manufacturing corresponding to operation 150, in accordance with some embodiments. At operation 150, a metal gap-fill material 264 is optionally deposited via a bottom-up metal fill process 262, at least partially, into the feature 222. In some embodiments, the bottom-up metal fill process 262 may completely fill the feature 222 as is shown in FIG. 2G.

In other embodiments, the bottom-up metal fill process 262 may partially fill the feature 222 at operation 160 followed as shown in FIG. 2E by a nitrogen plasma treatment 272 at operation 170 as shown in FIG. 2F. The nitrogen plasma treatment 272 at operation 170 may be performed similarly to the nitrogen plasma treatment of operation 140. In some embodiments, the nitrogen passivation layer 254 formed during operation 140 may dissipate after a certain amount of time. The nitrogen plasma treatment 272 at operation 170 reforms the nitrogen passivation layer 254 on exposed surfaces over the sidewalls, the overhang portion 234, and the upper surface 220u or field region as shown in FIG. 2E. Reforming the nitrogen passivation layer 254 at operation 170 enables bottom-up metal fill to continue with the metal gap-fill material 264. Operation 160 and operation 170 may be repeated until the feature 222 is filled to a targeted level as is shown in FIG. 2G.

In some embodiments, the metal gap-fill material 264 is formed using a CVD process including concurrently flowing (co-flowing) a tungsten-containing precursor gas, and a reducing agent into the processing region and exposing the semiconductor device structure 200 thereto. The tungsten-containing precursor and the reducing agent used for the tungsten gap-fill CVD process may include any combination of the tungsten-containing precursors and reducing agents described herein. In some embodiments, the tungsten-containing precursor includes WF₆, and the reducing agent includes hydrogen gas. In some embodiments, the metal gap-fill material 264 partially fills the features 222.

In some embodiments, the tungsten-containing precursor is flowed into the processing region at a flow rate in a range from about 10 sccm to about 1200 sccm, or more than about 50 sccm, or less than about 1000 sccm, or in a range from about 100 sccm to about 900 sccm. The reducing agent is flowed into the processing region at a rate of more than about 500 sccm, such as more than about 750 sccm, more than about 1000 sccm, or in a range from about 500 sccm and about 10000 sccm, such as in a range from about 1000 sccm to about 9000 sccm, or in a range from about 1000 sccm and about 8000 sccm.

In some embodiments, the tungsten gap-fill CVD process conditions are selected to provide a tungsten feature having a relativity low residual film stress when compared to conventional tungsten CVD processes. For example, in some embodiments, the tungsten gap-fill CVD process includes heating the substrate at a temperature of about 250° C. or more, such as about 300° C. or more, or in a range from about 250° C. to about 500° C., or in a range from about 300° C. to about 500° C. During the CVD process, the processing region may be maintained at a pressure of less than about 500 Torr, less than about 600 Torr, less than about 500 Torr, less than about 400 Torr, or in a range from about 1 Torr to about 500 Torr, such as in a range from about 1 Torr to about 450 Torr, or in a range from about 1 Torr to about 400 Torr, or for example, in a range from about 1 Torr and about 300 Torr.

In another embodiment, the metal gap-fill material 264 is deposited at operation 160 using an atomic layer deposition (ALD) process. The tungsten gap-fill ALD process includes repeating cycles of alternately exposing the semiconductor device structure 200 to a tungsten-containing precursor gas and a reducing agent and purging the processing region between the alternating exposures.

The tungsten-containing precursor and the reducing agent are each flowed into the processing region for a duration of between about 0.1 seconds and about 10 seconds, such as between about 0.5 seconds and about 5 seconds. The processing region may be purged between the alternating exposures by flowing an inert purge gas, such as argon (Ar) or hydrogen, into the processing region for a duration in a range from about 0.1 seconds to about 10 seconds, such as in a range from about 0.5 seconds to about 5 seconds.

In other embodiments, the metal gap-fill material 264 is deposited using a pulsed CVD method that includes repeating cycles of alternately exposing the semiconductor device structure 200 to a tungsten-containing precursor gas and a reducing gas without purging the processing region. The processing conditions for the tungsten gap-fill pulsed CVD method may be the same, substantially the same, or within the same ranges as those described above for the tungsten gap-fill ALD process.

FIG. 2H illustrates a cross-sectional view of the semiconductor device structure 200 during intermediate stages of manufacturing corresponding to operation 180, in accordance with some embodiments. At operation 180, the semiconductor device structure 200 may be exposed to additional processing 282. In some embodiments, the additional processing 282 includes a planarization process, for example a chemical mechanical polishing (CMP) process or an etchback process may be performed to remove excess portions or overburden of the conductive material (if present) on the upper surface 220u of the dielectric layer 220. After completing the planarization process, a top surface 284 of the metal gap-fill material 264 may be co-planar or level with the upper surface 220u of the dielectric layer and the top surfaces of the nucleation layer 240 and the one or more conformal/nonconformal layers 230 as is shown in FIG. 2H. In some embodiments, an annealing process may be performed during operation 180.

In some embodiments, as is shown in FIG. 2H, the one or more conformal/nonconformal layers 230, the nucleation layer 240, and the metal gap-fill material 264 are monolithic and do not have an interface therebetween. The metal gap-fill material 264, the one or more conformal/nonconformal layers 230, and the nucleation layer 240 together form a metal gap-fill layer or tungsten-containing layer.

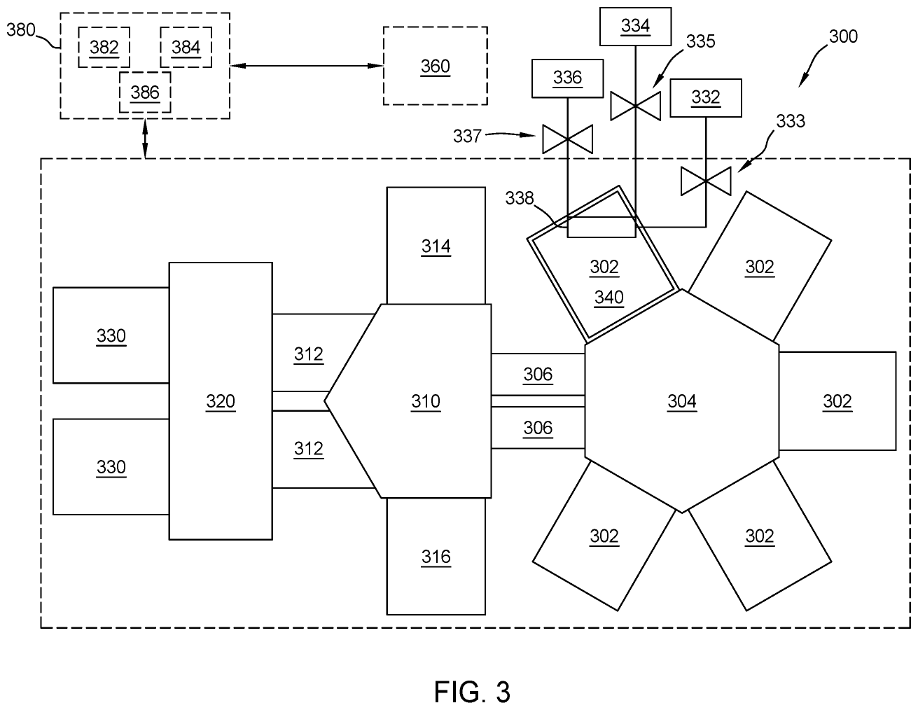

Examples of a processing system that may be suitably modified in accordance with the teachings provided herein include an integrated processing system or other suitable processing systems commercially available from Applied Materials, Inc., located in Santa Clara, California. It is contemplated that other processing systems (including those from other manufacturers) may be adapted to benefit from aspects described herein. FIG. 3 illustrates a schematic top-view diagram of an example multi-chamber processing system 300 or cluster tool that can be used to complete a gradient oxidation and etch of a PVD metal followed by a post-etch treatment process according to embodiments of the present disclosure. As shown in FIG. 3, a plurality of process chambers 302 is coupled to a first transfer chamber 304. The first transfer chamber 304 is also coupled to a first pair of pass-through chambers 306. The first transfer chamber 304 has a centrally disposed transfer robot (not shown) for transferring substrates between the pass-through chambers 306 and the process chambers 302. The pass-through chambers 306 are coupled to a second transfer chamber 310, which is coupled to a process chamber 314 that is configured to perform pre-clean process and a process chamber 316 that is configured to perform an epitaxial or alternatively, a PVD deposition process. The second transfer chamber 310 has a centrally disposed transfer robot (not shown) for transferring substrates between a set of load lock chamber 312 and the process chamber 314 or the process chamber 316. A factory interface 320 is connected to the second transfer chamber 310 by the load lock chambers 312. The factory interface 320 is coupled to one or more pods 330 on the opposite side of the load lock chambers 312. The pods 330 typically are front opening unified pods (FOUP) that are accessible from a clean room.

Prior to various operations, a substrate may first be transferred to the process chamber 314 where a pre-clean process is performed to remove contaminant, such as carbon or oxide contaminant from exposed surface of a source/drain region of a transistor of the substrate.

The substrate is then transferred to one or more of the process chambers 302. In some embodiments, the process chamber 302 may etch a via or a trench in the substrate. In some embodiments, the substrate is provided to an etch chamber, which is not a part of the processing system that contains the process chambers 314, 316 and the one or more process chambers 302, to perform the trench formation process. In other operations, the substrate is provided with trenches formed therein. Once the trench is formed in the dielectric material, the substrate is transferred to the process chamber 314 for cleaning.

Then the substrate is transferred to the process chamber 316 and/or at least one of the process chambers 302 where operations are performed. For example, the substrate is transferred to at least one of the process chambers 302 where a metal deposition operation is performed to form a seed layer. The metal can be deposited in any suitable chamber such as a PVD, atomic layer deposition (ALD), epitaxial (EPI) or other suitable chamber.

The substrate may be transferred to one of the process chambers 302 where a gradient oxidation operation may be performed. The gradient oxidation may be performed in an inductively coupled plasma (ICP) reactor or other suitable plasma process chamber. The gradient oxidation operation is configured to oxidize unwanted portions of the metal layer formed on the substrate.

The substrate may be transferred to one of the process chambers 302 where an etch operation is performed to selectively remove the oxidized portions of the deposited metal layer. For example, the etch operation may be performed in an etch chamber. Alternately, the etch operation may be performed in the ICP reactor in which the gradient oxidation was performed.

After the etch operation the substrate may be transferred to one of the process chambers 302 where a post-etch treatment process is performed to reduce tungsten oxide to tungsten and optionally remove contaminants from the tungsten surface. For example, the post-etch treatment process may be performed in the ICP reactor in which the gradient oxidation and etchback were performed. The post-etch treatment process may be a CVT process, for example, a hydrogen and oxygen treatment process as described herein.

After the post-etch treatment process a portion of the deposited metal layer (e.g., seed material) will remain along the sidewall surfaces and the bottom surfaces of the feature or trench. The substrate can then be transferred to one of the process chambers 302 or 316 where a gap-fill operation is performed. The gap-fill operation may be performed in a CVD, ALD or other suitable chamber. For example, process chamber 302 or 316 may deposit a metal such as tungsten or other suitable material for growth from the seed layer at the bottom of the trench or feature for forming a portion of a microelectronic device.

A system controller 380 is coupled to the processing system 300 for controlling the processing system 300 or components thereof. For example, the system controller 380 may control the operations of the processing system 300 using a direct control of the process chambers 302, 304, 306, 310, 312, 314, 316, 320, 330 of the processing system 300 or by controlling controllers associated with the process chambers 302, 304, 306, 310, 312, 314, 316, 320, 330, 360. In operation, the system controller 380 enables data collection and feedback from the respective chambers to coordinate performance of the processing system 300.

The system controller 380 generally includes a central processing unit (CPU) 382, memory 384, and support circuits 386. The CPU 382 may be one of any form of a general purpose processor that can be used in an industrial setting. The memory 384, non-transitory computer-readable medium, or machine-readable storage device, is accessible by the CPU 382 and may be one or more of memory such as random access memory (RAM), read only memory (ROM), floppy disk, hard disk, or any other form of digital storage, local or remote. The support circuits 386 are coupled to the CPU 382 and may comprise cache, clock circuits, input/output subsystems, power supplies, and the like. The various embodiments disclosed in this disclosure may generally be implemented under the control of the CPU 382 by executing computer instruction code stored in the memory 384 (or in memory of a particular process chamber) as, e.g., a computer program product or software routine. That is, the computer program product is tangibly embodied on the memory 384 (or non-transitory computer-readable medium or machine-readable storage device). When the computer instruction code is executed by the CPU 382, the CPU 382 controls the chambers to perform operations in accordance with the various embodiments.

The system controller 380 is configured to perform methods such as the method 100 stored in the memory 384.

In some embodiments, the first process chamber 302 includes a nitrogen-containing gas source 332 that is fluidly coupled to a processing region 340 of the first process chamber 302, wherein the nitrogen-containing gas source 332 is configured to deliver a nitrogen-containing gas to the processing region 340. The first process chamber 302 may further include a first flow control valve 333 that is configured to control the flow of nitrogen-containing gas provided from the nitrogen-containing gas source 332 to the processing region 340. In some embodiments, the first process chamber 302 further includes a non-reactive gas source 334 that is fluidly coupled to the processing region 340 of the first process chamber 302, wherein the non-reactive gas source 334 is configured to deliver a noble or inert gas to the processing region 340. The first process chamber 302 may further include a second flow control valve 335 that is configured to control the flow of the non-reactive gas provided from the non-reactive gas source 334 to the processing region 340. The first process chamber 302 may further include an inductively coupled plasma source or capacitively coupled plasma source 338 that is configured to generate a plasma in the processing region 340, wherein the plasma is formed from the nitrogen-containing gas and the non-reactive gas.

In other embodiments, the first process chamber 302 includes a remote plasma source (RPS) 336 that is fluidly coupled to the processing region 340 of the first process chamber 302, wherein the RPS 336 is configured to deliver a remote plasma to the processing region 340. The first process chamber 302 may further include a third flow control valve 337 that is configured to control the flow of the remote plasma provided from the RPS 336 to the processing region 340. In some embodiments that include an RPS, the non-reactive gas source 334 and the nitrogen-containing gas source 332 are fluidly coupled with the RPS (not shown).

In some embodiments, the system controller 380 is configured to control the first flow control valve 333 and the second flow control valve 335 so that an amount of nitrogen-containing gas and non-reactive gas are provided to the processing region 340 of the first process chamber 302, to preferentially passivate one or more tungsten-containing layers disposed on a field region and sidewalls of features formed in the substrate by generating plasma in the processing region 340 of first process chamber 302.

In other embodiments, the system controller is configure to control the third flow control valve 337 so that an amount of remote plasma formed from at least the nitrogen-containing gas is provided to the processing region 340 of the first process chamber 302, to preferentially passivate one or more tungsten-containing layers disposed on a field region and sidewalls of features formed in the substrate.

Embodiments and all of the functional operations described in this specification can be implemented in digital electronic circuitry, or in computer software, firmware, or hardware, including the structural means disclosed in this specification and structural equivalents thereof, or in combinations of them. Embodiments described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

When introducing elements of the present disclosure or exemplary aspects or embodiment(s) thereof, the articles “a,” “an,” “the” and “said” are intended to mean that there are one or more of the elements.

While the foregoing is directed to embodiments of the present disclosure, other and further embodiments of the disclosure may be devised without departing from the basic scope thereof, and the scope thereof is determined by the claims that follow.

1. A method for processing a semiconductor device structure in a process chamber, comprising:
generating a plasma comprising nitrogen-containing radicals in a remote plasma source, wherein the plasma is formed from a process gas comprising nitrogen and a noble gas;
flowing the plasma comprising nitrogen-containing radicals into a processing region of the process chamber where the semiconductor device structure is disposed, wherein the semiconductor device structure has:
a feature formed thereon, the feature having sidewall surfaces and a bottom surface extending between the sidewall surfaces; and
a tungsten nucleation layer formed over the sidewall surfaces and the bottom surface;
exposing an exposed portion of the tungsten nucleation layer along the sidewall surface of the tungsten nucleation layer to the nitrogen-containing radicals to passivate the exposed portion of the tungsten nucleation layer, wherein the tungsten nucleation layer formed along the bottom surface remains substantially un-passivated; and
filling the feature with a tungsten layer, comprising preferentially growing the tungsten layer from the tungsten nucleation layer remaining on the bottom surface of the feature.

2. The method of claim 1, further comprising maintaining a pressure within the processing region such that a nitrogen partial pressure in the processing region in a range from about 5 milliTorr to about 20 milliTorr.

3. The method of claim 2, wherein the pressure within the processing region is maintained in a range from about 1 Torr to about 10 Torr.

4. The method of claim 1, wherein exposing the exposed portion of the tungsten nucleation layer along the sidewall surface of the tungsten nucleation layer to the nitrogen-containing radicals is performed for a time period in a range from about 5 seconds to about 40 seconds.

5. The method of claim 1, further comprising filtering out ions delivered from the remote plasma source to the processing region.

6. The method of claim 1, further comprising filtering ions from an output of the remote plasma source.

7. The method of claim 1, wherein filling the feature with the tungsten layer is performed in the processing region.

8. The method of claim 1, wherein the process gas comprises from about 5% to about 20% nitrogen and the remainder the noble gas, wherein the noble gas is argon.

9. A method for processing a semiconductor device structure in a process chamber, comprising:
generating a plasma comprising nitrogen-containing ions using an inductively coupled plasma source, wherein the plasma is formed from a process gas comprising nitrogen and a noble gas;
flowing the plasma comprising the nitrogen-containing ions into a processing region of the process chamber where the semiconductor device structure is disposed, wherein the semiconductor device structure has:
a feature formed thereon, the feature having sidewall surfaces and a bottom surface extending between the sidewall surfaces; and
a tungsten nucleation layer formed over the sidewall surfaces and the bottom surface;
exposing an exposed portion of the tungsten nucleation layer along the sidewall surface of the tungsten nucleation layer to the nitrogen-containing ions to passivate the exposed portion of the tungsten nucleation layer, wherein the tungsten nucleation layer formed along the bottom surface remains substantially un-passivated; and
filling the feature with a tungsten layer, comprising preferentially growing the tungsten layer from the tungsten nucleation layer remaining on the bottom surface of the feature.

10. The method of claim 9, further comprising maintaining a pressure within the processing region such that a nitrogen partial pressure in the processing region is in a range from about 0.01 milliTorr to about 0.05 milliTorr.

11. The method of claim 10, wherein the pressure within the processing region is maintained in a range from about 5 milliTorr to about 20 milliTorr.

12. The method of claim 9, wherein exposing the exposed portion of the tungsten nucleation layer along the sidewall surface of the tungsten nucleation layer to the nitrogen-containing ions is performed for a time period in a range from about 3 seconds to about 20 seconds.

13. The method of claim 9, further comprising filtering out radicals delivered from the ICP source to the processing region.

14. The method of claim 9, further comprising filtering radicals from an output of the ICP source.

15. The method of claim 9, wherein filling the feature with the tungsten layer is performed in the processing region.

16. The method of claim 9, wherein the process gas comprises from about 1% to about 10% nitrogen and the remainder the noble gas, wherein the noble gas is argon.

17. A method for processing a semiconductor device structure in a process chamber, comprising:
exposing a semiconductor device structure to nitrogen-containing ions in a processing region of the process chamber, the semiconductor device structure having:
a feature formed thereon, the feature having sidewall surfaces and a bottom surface extending between the sidewall surfaces;
one or more conformal/nonconformal layers formed over the sidewall surfaces and the bottom surface; and
a boron-tungsten nucleation layer formed over the one or more conformal/nonconformal layers, wherein an exposed portion of the tungsten nucleation layer along the sidewall surface of the tungsten nucleation layer is passivated by the nitrogen-containing ions to suppress subsequent tungsten growth, and the boron-tungsten nucleation layer formed along the bottom surface remains substantially un-passivated; and
partially filling the feature with a tungsten layer, comprising preferentially growing the tungsten layer from the tungsten nucleation layer remaining on the bottom surface of the feature; and
repeating the exposing the semiconductor device structure to nitrogen-containing ions in the processing region and partially filing the feature with the tungsten layer until the tungsten layer achieves a targeted thickness.

18. The method of claim 17, further comprising maintaining a pressure within the processing region such that a nitrogen partial pressure in the processing region is in a range from about 0.01 milliTorr to about 0.05 milliTorr.

19. The method of claim 18, wherein the pressure within the processing region is maintained in a range from about 5 milliTorr to about 20 milliTorr.

20. The method of claim 19, wherein exposing the exposed portion of the boron-tungsten nucleation layer along the sidewall surface to the nitrogen-containing ions is performed for a time period in a range from about 3 seconds to about 20 seconds.
